(19) United States
(12) Patent Application Publication
(10) Pub. No.: US 2026/0280218 A1
(43) Pub. Date: Sep. 17, 2026

(54) LASER CHAMBER, GAS LASER DEVICE, AND ELECTRONIC DEVICE MANUFACTURING METHOD

(71) Applicant: Gigaphoton Inc., Tochigi (JP)

(72) Inventor: Hitoshi OHGA, Tochigi (JP)

(73) Assignee: Gigaphoton Inc., Tochigi (JP)

(21) Appl. No.: 19/529,007

(22) Filed: Feb. 3, 2026

(30) Foreign Application Priority Data
Mar. 14, 2025 (JP) 2025-041918

(51) Int. Cl. H01S 3/036; G03F 7/00; G03F 7/20; H10P 76/00

(52) U.S. Cl. CPC H01S 3/036; G03F 7/2004; G03F 7/70025; H10P 76/00

(57) ABSTRACT

A laser chamber includes a container configured to accommodate a laser gas; a discharge electrode configured of a pair of electrodes arranged in the container; a cross flow fan including a fan body configured to cause the laser gas to circulate in the container, and a rotary shaft protruding from both sides of the fan body; and a pair of first guides arranged opposite to each other in an axis direction of the rotary shaft so as to sandwich at least a part of the fan body, and configured to rectify the laser gas toward a discharge space between the pair of electrodes.

### CROSS-REFERENCE TO RELATED APPLICATIONS

The present application claims the benefit of Japanese Patent Application No. 2025-041918, filed on Mar. 14, 2025, the entire contents of which are hereby incorporated by reference.

### BACKGROUND

### 1. Technical Field

The present disclosure relates to a laser chamber, a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: International Publication No. WO2022/201844

Patent Document 2: Japanese Patent No. 2997606

### SUMMARY

A laser chamber according to an aspect of the present disclosure includes a container configured to accommodate a laser gas; a discharge electrode configured of a pair of electrodes arranged in the container; a cross flow fan including a fan body configured to cause the laser gas to circulate in the container, and a rotary shaft protruding from both sides of the fan body; and a pair of first guides arranged opposite to each other in an axis direction of the rotary shaft so as to sandwich at least a part of the fan body, and configured to rectify the laser gas toward a discharge space between the pair of electrodes.

A gas laser device according to an aspect of the present disclosure includes an optical resonator and a laser chamber arranged such that an optical path of the optical resonator passes therethrough and is configured to output laser light. Here, the laser chamber includes a container configured to accommodate a laser gas; a discharge electrode configured of a pair of electrodes arranged in the container; a cross flow fan including a fan body configured to cause the laser gas to circulate in the container, and a rotary shaft protruding from both sides of the fan body; and a pair of first guides arranged opposite to each other in an axis direction of the rotary shaft so as to sandwich at least a part of the fan body, and configured to rectify the laser gas toward a discharge space between the pair of electrode.

An electronic device manufacturing method according to an aspect of the present disclosure includes generating laser light using a gas laser device, outputting the laser light to an exposure apparatus, and exposing a photosensitive substrate to the laser light in the exposure apparatus to manufacture an electronic device. Here, the gas laser device includes an optical resonator and a laser chamber arranged such that an optical path of the optical resonator passes therethrough and is configured to output the laser light. The laser chamber includes a container configured to accommodate a laser gas; a discharge electrode configured of a pair of electrodes arranged in the container; a cross flow fan including a fan body configured to cause the laser gas to circulate in the container, and a rotary shaft protruding from both sides of the fan body; and a pair of first guides arranged opposite to each other in an axis direction of the rotary shaft so as to sandwich at least a part of the fan body, and configured to rectify the laser gas toward a discharge space between the pair of electrode.

### BRIEF DESCRIPTION OF THE DRAWINGS

Embodiments of the present disclosure will be described below merely as examples with reference to the accompanying drawings.

FIG. 1 is a side view schematically showing the configuration of a gas laser device according to a comparative example.

FIG. 2 is a sectional view schematically showing the configuration of the gas laser device according to the comparative example.

FIG. 3 is a sectional view showing the flow of a laser gas according to the comparative example.

FIG. 4 is a view showing the configuration of a laser chamber according to a first embodiment.

FIG. 5 is a view showing the configuration of the laser chamber according to a second embodiment.

FIG. 6 is a perspective view showing a first guide and an outer guide according to the second embodiment.

FIG. 7 is a view showing the configuration of the laser chamber according to a third embodiment.

FIG. 8 is a view showing the configuration of the laser chamber according to a fourth embodiment.

FIG. 9 is a view showing the configuration of the laser chamber according to a fifth embodiment.

FIG. 10 is a perspective view showing an introduction port and a partition wall according to the fifth embodiment.

FIG. 11 is a diagram schematically showing a configuration example of an exposure apparatus.

### DESCRIPTION OF EMBODIMENTS

### Contents

1. Comparative example
   1.1 Configuration
   1.2 Operation
   1.3 Problem
2. First embodiment
   2.1 Configuration
   2.2 Operation
   2.3 Effect
3. Second embodiment
   3.1 Configuration
   3.2 Operation
   3.3 Effect
4. Third embodiment
   4.1 Configuration
   4.2 Operation
   4.3 Effect
5. Fourth embodiment
6. Fifth embodiment
   6.1 Configuration
   6.2 Operation
   6.3 Effect
7. Electronic device manufacturing method

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

First, a comparative example of the present disclosure will be described. The comparative example of the present disclosure is an example recognized by the applicant as known only by the applicant, and is not a publicly known example admitted by the applicant.

### 1.1 Configuration

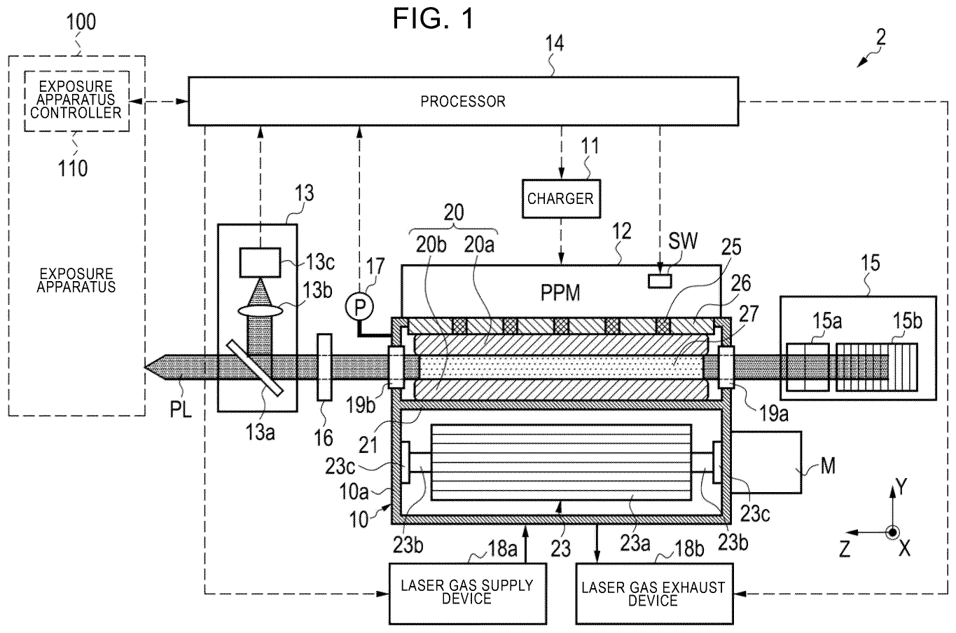

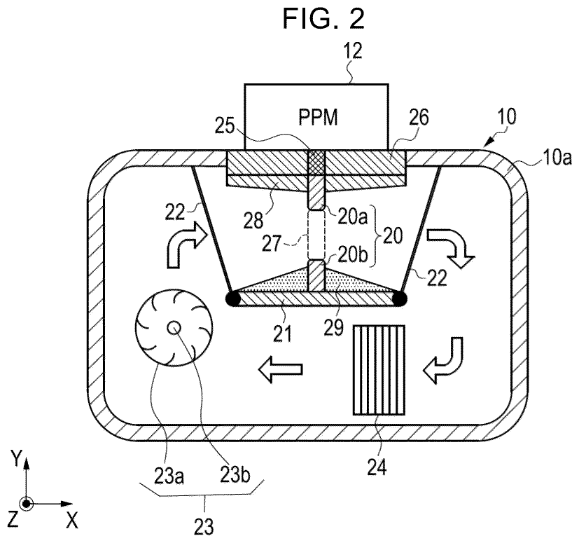

The configuration of a gas laser device 2 according to the comparative example will be described using FIGS. 1 and 2. FIG. 1 schematically shows the configuration of the gas laser device 2. FIG. 2 is a sectional view of the gas laser device 2 shown in FIG. 1 viewed from a Z direction. The gas laser device 2 is a discharge-excitation-type gas laser device that causes discharge and excites a laser gas, and is, for example, an excimer laser device.

In FIG. 1, the travel direction of the pulse laser light PL output from the gas laser device 2 is defined as the Z direction. A discharge direction to be described later is defined as a Y direction. A direction orthogonal to the Z direction and the Y direction is defined as an X direction. Here, the pulse laser light PL is an example of the “laser light” according to the technology of the present disclosure.

In FIG. 1, the gas laser device 2 includes a laser chamber 10, a charger 11, a pulse power module (PPM) 12, a pulse energy measurement unit 13, a processor 14, a pressure sensor 17, and a laser resonator. The laser resonator is configured of a line narrowing module 15 and an output coupling mirror 16.

The laser chamber 10 includes, for example, a container 10a made of aluminum metal plated with nickel on the surface thereof. As shown in FIGS. 1 and 2, a discharge electrode 20, a ground plate 21, wirings 22, a fan 23, a heat exchanger 24, an insulating guide 28, and a conductive guide 29 are provided in the container 10a.

A laser gas containing fluorine as a laser medium is enclosed in the container 10a. The laser gas includes, for example, argon, krypton, xenon, or the like as a rare gas, neon, helium, or the like as a buffer gas, and fluorine, chlorine, or the like as a halogen gas.

Further, an opening is formed in the container 10a. An electrically insulating plate 26 in which a feedthrough 25 is embedded is attached to the container 10a via an O-ring (not shown) so as to close the opening. The PPM 12 is arranged on the electrically insulating plate 26. The container 10a is grounded.

The PPM 12 includes a charging capacitor (not shown) and is connected to the discharge electrode 20 via the feedthrough 25. The PPM 12 includes a switch SW for causing discharge to occur at the discharge electrode 20. The charger 11 is connected to the charging capacitor of the PPM 12.

The discharge electrode 20 includes a cathode electrode 20a and an anode electrode 20b. The cathode electrode 20a and the anode electrode 20b are arranged in the container 10a so that discharge surfaces of the both face each other. The space between the discharge surface of the cathode electrode 20a and the discharge surface of the anode electrode 20b is referred to as a discharge space 27. Each of the cathode electrode 20a and the anode electrode 20b extends in the Z direction.

The cathode electrode 20a is supported by the electrically insulating plate 26 on a surface opposite to the discharge surface thereof, and is connected to the feedthrough 25. The anode electrode 20b is supported by the ground plate 21 on a surface opposite to the discharge surface thereof. The cathode electrode 20a and the anode electrode 20b are an example of the “pair of electrodes” according to the technology of the present disclosure.

The ground plate 21 is connected to the container 10a via the wirings 22. The container 10a is grounded. Therefore, the ground plate 21 is grounded via the wirings 22. An end part of the ground plate 21 in the Z direction is fixed to the container 10a.

The fan 23 is a cross flow fan for circulating the laser gas in the container 10a. The fan 23 is arranged on the opposite side of the discharge space 27 in the Y direction with respect to the ground plate 21. A motor M for rotationally driving the fan 23 is connected to the container 10a. The fan 23 includes a fan body 23a including blades and a rotary shaft 23b protruding from both sides of the fan body 23a. The fan body 23a has, for example, a generally long cylindrical shape, and the blades are formed on a circumferential surface of the cylindrical shape. The fan 23 is arranged in the container 10a such that the longitudinal direction of the fan body 23a is aligned with the Z direction. The rotary shaft 23b protrudes from both sides of the fan body 23a in the longitudinal direction thereof. The longitudinal direction of the fan body 23a is an axis direction of the rotary shaft 23b. The axis direction of the rotary shaft 23b is an example of the “axis direction of the rotary shaft” according to the technology of the present disclosure. One end of the rotary shaft 23b is rotatably supported, for example, by an inner wall of the container 10a via a bearing 23c.

As shown by arrows in FIG. 2, when the fan 23 rotates, the laser gas in the container 10a flows, and the laser gas flows in from the fan 23 toward the discharge space 27. The flow direction of the laser gas flowing into and passing through the discharge space 27 is substantially parallel to the X direction. The laser gas flowing out from the discharge space 27 is sucked into the fan 23 via the heat exchanger 24. The heat exchanger 24 changes the temperature of the laser gas by performing heat exchange between a refrigerant supplied to the inside of the heat exchanger 24 and the laser gas. Thus, the fan 23 circulates the laser gas in the container 10a.

The insulating guide 28 is arranged on a surface of the electrically insulating plate 26 facing the discharge space 27 so as to sandwich the cathode electrode 20a. The insulating guide 28 is formed in a shape to guide the flow of the laser gas so that the laser gas from the fan 23 efficiently flows between the cathode electrode 20a and the anode electrode 20b. The insulating guide 28 and the electrically insulating plate 26 are made of, for example, ceramics such as alumina (Al₂O₃) having low reactivity with a fluorine gas.

The conductive guide 29 is arranged on a surface of the ground plate 21 facing the discharge space 27 so as to sandwich the anode electrode 20b. Similarly to the insulating guide 28, the conductive guide 29 is formed in a shape to guide the flow of the laser gas so that the laser gas from the fan 23 efficiently flows between the cathode electrode 20a and the anode electrode 20b. The conductive guide 29 is made of, for example, a porous nickel metal having low reactivity with the fluorine gas.

Here, in the direction in which the laser gas flows from the fan 23 to the heat exchanger 24 in the container 10a, that is, in the flow direction of the laser gas passing through the discharge space 27, the side where the laser gas flows into the discharge space 27 with respect to the discharge space 27 is referred to as an upstream side, and the side where the laser gas flows out from the discharge space 27 with respect to the discharge space 27 is referred to as a downstream side.

Each of the insulating guide 28 and the conductive guide 29 has a substantially triangular sectional shape in which the position of the discharge electrode 20 is an apex as viewed from the Z direction, and the apexes thereof face each other. Therefore, in the flow path through which the laser gas flows, the width in the Y direction gradually decreases from the upstream side toward the discharge space 27, and gradually increases from the discharge space 27 toward the downstream side. By forming the insulating guide 28 and the conductive guide 29 in such shapes, the flow velocity of the laser gas in the discharge space 27 is increased, and elimination of discharge products generated by the discharge in the discharge space 27 is promoted.

A laser gas supply device 18a and a laser gas exhaust device 18b are connected to the laser chamber 10. The laser gas supply device 18a includes a valve and a flow rate control valve, and is connected to a gas cylinder accommodating the laser gas. The laser gas exhaust device 18b includes a valve and an exhaust pump.

At end parts of the container 10a, windows 19a, 19b for outputting light generated in the container 10a to the outside are provided, respectively. The laser chamber 10 is arranged such that the optical path of the optical resonator passes through the discharge space 27 and the windows 19a, 19b.

The line narrowing module 15 includes a prism 15a and a grating 15b. The prism 15a transmits the light output from the laser chamber 10 through the window 19a toward the grating 15b while expanding the beam width of the light.

The grating 15b is arranged in the Littrow arrangement so that the incident angle and the diffraction angle are the same. The grating 15b is a wavelength selection element that selectively extracts light having a wavelength near a particular wavelength in accordance with the diffraction angle. The spectral width of the light returning from the grating 15b to the laser chamber 10 via the prism 15a is line-narrowed.

The output coupling mirror 16 transmits a part of the light output from the laser chamber 10 through the window 19b, and reflects the other part back into the laser chamber 10. The surface of the output coupling mirror 16 is coated with a partial reflection film.

Light output from the laser chamber 10 reciprocates between the line narrowing module 15 and the output coupling mirror 16, and is amplified each time the light passes through the discharge space 27. A part of the amplified light is output as the pulse laser light PL via the output coupling mirror 16. The wavelength of the pulse laser light PL is in an ultraviolet range of 150 nm to 380 nm, and is, for example, an oscillation wavelength of an excimer laser device.

The pulse energy measurement unit 13 is arranged on the optical path of the pulse laser light PL output via the output coupling mirror 16. The pulse energy measurement unit 13 includes a beam splitter 13a, a light concentrating optical system 13b, and an optical sensor 13c.

The beam splitter 13a transmits the pulse laser light PL with a high transmittance and reflects a part of the pulse laser light PL toward the light concentrating optical system 13b. The light concentrating optical system 13b concentrates the light reflected by the beam splitter 13a on a light receiving surface of the optical sensor 13c. The optical sensor 13c measures the pulse energy of the light concentrated on the light receiving surface, and outputs the measurement value to the processor 14.

The pressure sensor 17 detects the gas pressure in the container 10a, and outputs the detection value to the processor 14. The processor 14 determines the gas pressure of the laser gas in the container 10a based on the detection value of the gas pressure and the charge voltage of the charger 11.

The charger 11 is a high voltage power source that supplies the charge voltage to the charging capacitor included in the PPM 12. The switch SW of the PPM 12 is controlled by the processor 14. When the switch SW is turned ON from OFF, the PPM 12 generates a high voltage pulse from the electric energy held in the charging capacitor and applies the high voltage pulse to the discharge electrode 20.

The processor 14 is a processing device that transmits and receives various signals to and from an exposure apparatus controller 110 provided in an exposure apparatus 100. For example, the exposure apparatus controller 110 transmits, to the processor 14, a target pulse energy of the pulse laser light PL to be output to the exposure apparatus 100, an oscillation trigger signal, and the like.

The processor 14 generally controls operation of each component of the gas laser device 2 based on various signals transmitted from the exposure apparatus controller 110, the measurement value of the pulse energy, the detection value of the gas pressure, and the like.

The processor 14 functions as a controller of the gas laser device 2. For example, the processor 14 is a processing device including a storage device in which a control program is stored and a central processing unit (CPU) that executes the control program. The processor 14 is specifically configured or programmed to perform various processes included in the present disclosure. The storage device is a non-transitory computer-readable storage medium, and includes, for example, a memory that is a main storage device and a storage that is an auxiliary storage device. Here, the storage device may be a semiconductor memory, a hard disk drive (HDD) device, a solid state drive (SSD) device, or a combination thereof.

Here, the gas laser device 2 is not necessarily limited to a line narrowing laser device, and may be a laser device that outputs natural oscillation light. For example, a high reflection mirror may be arranged in place of the line narrowing module 15.

### 1.2 Operation

Next, operation of the gas laser device 2 according to the comparative example will be described. First, the processor 14 controls the laser gas supply device 18a to supply the laser gas into the container 10a of the laser chamber 10, and drives the motor M to rotate the fan 23. As a result, as indicated by arrows in FIG. 2, the laser gas filled in the container 10a circulates.

The processor 14 receives the target pulse energy and the oscillation trigger signal transmitted from the exposure apparatus controller 110. Here, the oscillation trigger signal is a signal for instructing the gas laser device 2 to output one pulse of the pulse laser light PL.

The processor 14 sets the charge voltage corresponding to the target pulse energy in the charger 11. The processor 14 operates the switch SW of the PPM 12 in synchronization with the oscillation trigger signal.

When the switch SW of the PPM 12 is turned ON from OFF, a voltage is applied between the cathode electrode 20a and the anode electrode 20b. Accordingly, discharge occurs in the discharge space 27. When the discharge direction is defined as a direction in which electrons flow, the discharge direction is the direction from the cathode electrode 20a toward the anode electrode 20b. When discharge occurs, the laser gas in the discharge space 27 is excited to emit ultraviolet (UV) light.

The shapes of the insulating guide 28 and the conductive guide 29 improve the flow velocity of the laser gas passing through the discharge space 27. Therefore, the discharge products generated by discharge in the discharge space 27 are flushed away by the time of the next discharge, and discharge is stabilized.

The light emitted from the laser gas is reflected by the line narrowing module 15 and the output coupling mirror 16 and reciprocates in the laser resonator, thereby performing laser oscillation. The light line-narrowed by the line narrowing module 15 is output from the output coupling mirror 16 as the pulse laser light PL.

A part of the pulse laser light PL output from the output coupling mirror 16 enters the pulse energy measurement unit 13. The pulse energy measurement unit 13 measures the pulse energy of the entering pulse laser light PL, and outputs the measurement value to the processor 14.

The processor 14 calculates a difference ΔE between the measurement value of the pulse energy and the target pulse energy. The processor 14 performs feedback control on the charge voltage based on the difference ΔE so that the measurement value of the pulse energy becomes the target pulse energy.

When the charge voltage is higher than a maximum value of an allowable range, the processor 14 controls the laser gas supply device 18a to supply the laser gas into the container 10a until a predetermined pressure is reached. Further, when the charge voltage is lower than a minimum value of the allowable range, the processor 14 controls the laser gas exhaust device 18b to exhaust the laser gas from the container 10a until a predetermined pressure is reached.

The pulse laser light PL transmitted through the pulse energy measurement unit 13 enters the exposure apparatus 100.

### 1.3 Problem

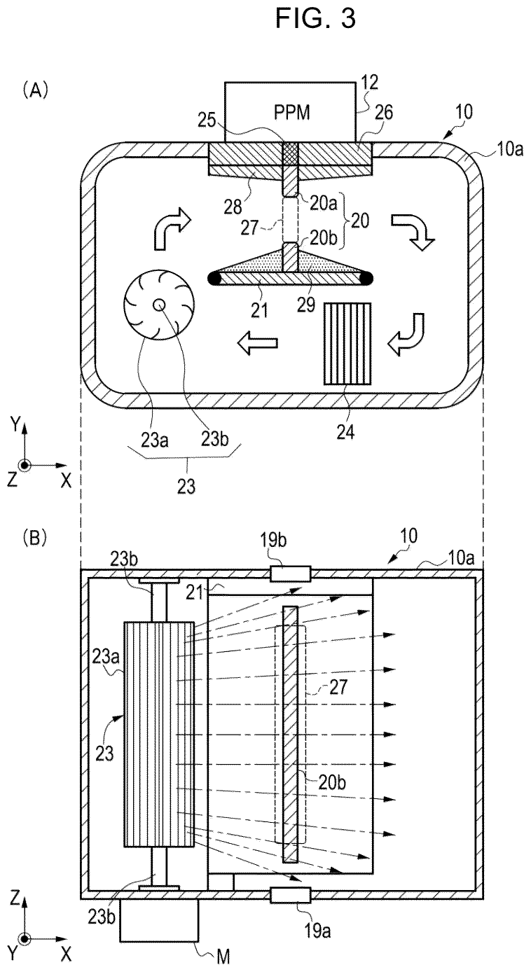

FIG. 3 shows in detail the flow of the laser gas circulating in the container 10a. (A) of FIG. 3 is a side view of the container 10a taken from the same direction as FIG. 2, and (B) of FIG. 3 is a plan view of the container 10a. In (A) of FIG. 3, the wirings 22 are omitted to avoid complication of the drawing. As shown in (B) of FIG. 3, the longitudinal direction (Z direction) of the discharge space 27 is the axis direction of the fan 23, and a length L of the fan body 23a of the fan 23 in the axis direction is a length substantially corresponding to the length of the discharge space 27 in the longitudinal direction. Therefore, the laser gas flows from the upstream side toward the downstream side over the entire region in the longitudinal direction of the discharge space 27. In the vicinity of the center of the discharge space 27 in the longitudinal direction, the laser gas travels straight along the X direction orthogonal to the longitudinal direction from the upstream side toward the downstream side.

However, in the vicinity of the end of the discharge space 27 in the longitudinal direction, the laser gas sometimes diffuses to the outside of the discharge space 27. The cause is as follows. As shown in (A) of FIG. 3, each of the insulating guide 28 and the conductive guide 29 has a substantially triangular sectional shape in which the position of the discharge electrode 20 is an apex, and the apexes thereof face each other. As described above, due to such shapes of the insulating guide 28 and the conductive guide 29, the flow velocity of the laser gas passing through the discharge space 27 increases, but the laser gas is compressed in the discharge space 27. Therefore, in the vicinity of the end of the discharge space 27 in the longitudinal direction, a part of the laser gas is pushed and diffused to the outside of the discharge space 27. When the laser gas is diffused, the flow velocity of the laser gas decreases, and therefore, in the vicinity of the end of the discharge space 27 in the longitudinal direction, elimination of the discharge products becomes insufficient, and discharge becomes unstable in some cases.

Therefore, an object of the present disclosure is to provide a laser chamber, a gas laser device, and an electronic device manufacturing method that can suppress a decrease in the flow velocity of the laser gas flowing in the vicinity of the end of the discharge space 27 in the longitudinal direction.

### 2. First Embodiment

### 2.1 Configuration

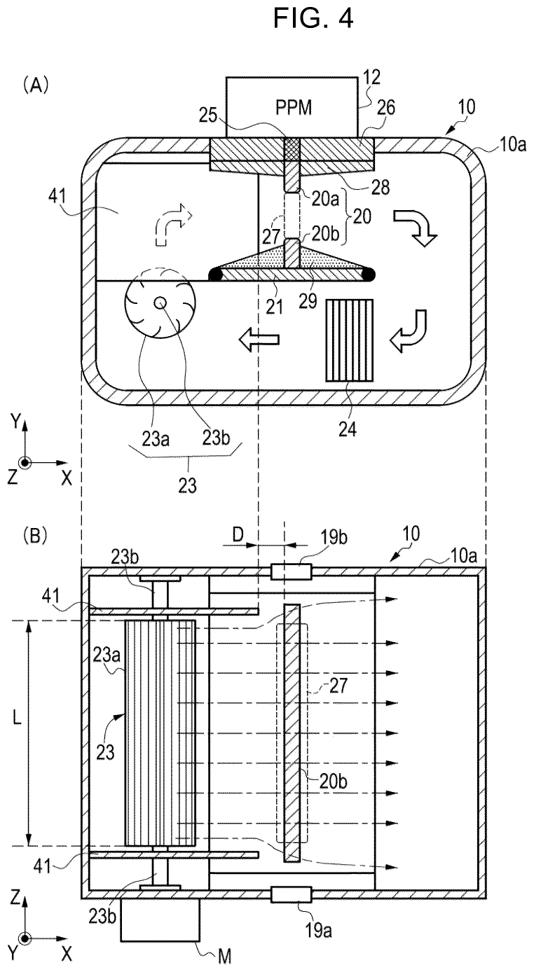

The gas laser device 2 according to a first embodiment of the present disclosure has a configuration similar to that of the gas laser device 2 according to the comparative example except that the configuration of the laser chamber 10 is different.
FIG. 4 shows the configuration of the laser chamber 10 according to the first embodiment. (A) of FIG. 4 is a side view of the container 10a, and (B) of FIG. 4 is a plan view of the container 10a. In the first embodiment, the container 10a includes a pair of first guides 41 arranged opposite to each other in the axis direction of the rotary shaft 23b so as to sandwich at least a part of the fan body 23a, and rectify the laser gas toward the discharge space 27 between the cathode electrode 20a and the anode electrode 20b. The pair of first guides 41 are arranged on the upstream side of the discharge space 27, which is on the fan 23 side, in the flow direction of the laser gas (X direction in FIG. 4) passing through the discharge space 27.

As an example, the pair of first guides 41 are each plate-shaped and extend in the flow direction of the laser gas passing through the discharge space 27. The flow direction of the laser gas passing through the discharge space 27 is an example of the “direction orthogonal to the axis direction of the rotary shaft” according to the technology of the present disclosure. The pair of first guides 41 each have a length such that the optical path of UV light between the windows 19a, 19b is not blocked in the flow direction of the laser gas. That is, in the X direction, which is the flow direction of the laser gas, the pair of first guides 41 are arranged as being spaced apart from the discharge electrode 20 by a distance D.

The pair of first guides 41 are formed of, for example, an insulating material. The pair of first guides 41 are arranged in a posture in which the plate surfaces thereof face each other, and cover a part of the fan body 23a as shown in (A) of FIG. 4. For example, the pair of first guides 41 are each fixed to the inner wall of the container 10a at the upstream ends thereof in the flow direction of the laser gas. The downstream ends thereof are fixed to the conductive guide 29.

For example, the pair of first guides 41 each extend at least to the bottom surface of the ground plate 21 in the discharge direction of the cathode electrode 20a and the anode electrode 20b. The ground plate 21 is a support member that supports the anode electrode 20b, and is an example of the “support member supporting an electrode closer to a cross flow fan out of a pair of electrodes” according to the technology of the present disclosure.

### 2.2 Operation

Operation of the gas laser device 2 according to the first embodiment is similar to that of the comparative example except that the effect caused by provision of the pair of first guides 41 in the container 10a is different.

As shown in (B) of FIG. 4, the laser gas flows toward the discharge space 27 due to the rotation of the fan 23. In the first embodiment, the pair of first guides 41 are arranged respectively on both sides of the fan body 23a. The flow of the laser gas toward the outside of the discharge space 27 in the longitudinal direction is restricted by the pair of first guides 41.

### 2.3 Effect

In the first embodiment, since the flow of the laser gas toward the outside of the discharge space 27 in the longitudinal direction is restricted by the pair of first guides 41, diffusion of the laser gas to the outside of the discharge space 27 in the longitudinal direction is suppressed. As a result, the decrease in the flow velocity of the laser gas in the vicinity of the end of the discharge space 27 in the longitudinal direction is suppressed, and the discharge products remaining in the discharge space 27 are reduced, so that the stability of the discharge is improved.

Further, since the pair of first guides 41 are each formed in a plate shape, the configuration is not complicated.

Further, since the lower end of each of the pair of first guides 41 is at a position equal to or lower than the lower end of the ground plate 21, it is possible to efficiently rectify the laser gas from above the fan 23 toward the discharge space 27 above the ground plate 21.

The pair of first guides 41 are each formed of an insulating material. Therefore, it is easy to extend the discharge electrode 20 to the vicinity of the discharge space 27. That is, the distance D can be shortened. Since the discharge space 27 serves as an optical path of the UV light, the first guide 41 should not block the optical path and is preferably brought as close to the discharge space 27 as possible. This is because the closer to the discharge space 27, the more the effect of suppressing the decrease in the flow velocity of the laser gas in the vicinity of the end of the discharge space 27 in the longitudinal direction is improved. When the first guide 41 is formed of an insulating material, it is possible to extend the first guide 41 closer to the discharge space 27 than when the first guide is formed of a conductive material such as a metal.

In the first embodiment, as long as the distance between the discharge space 27 and the first guide 41 is ensured so as not to affect the discharge, the first guide 41 may not be an insulating material, and may be formed of a conductive material such as a metal. Further, since the conductive guide 29 and the ground plate 21 are grounded, the first guide 41, the conductive guide 29, and the ground plate 21 may be electrically connected to each other even when the first guide 41 is formed of a conductive material. Further, the first guide 41 may be formed of a conductive material and an insulating material. In this case, the side close to the discharge space 27 may be formed of an insulating material, and the side far therefrom may be formed of a conductive material. Further, the first guide 41 may not be plate-shaped. Further, the upstream end of each of the pair of first guides 41 in the flow direction of the laser gas may not be in contact with the inner wall of the container 10a. Further, the downstream end may not be fixed to and may not be in contact with the conductive guide 29. Here, the pair of first guides 41 cover a part of the fan body 23a, but may cover all the fan body 23a except the rotary shaft 23b.

### 3. Second embodiment

### 3.1 Configuration

The gas laser device 2 according to a second embodiment of the present disclosure has a configuration similar to that of the gas laser device 2 according to the first embodiment except that the configuration of the laser chamber 10 is different.

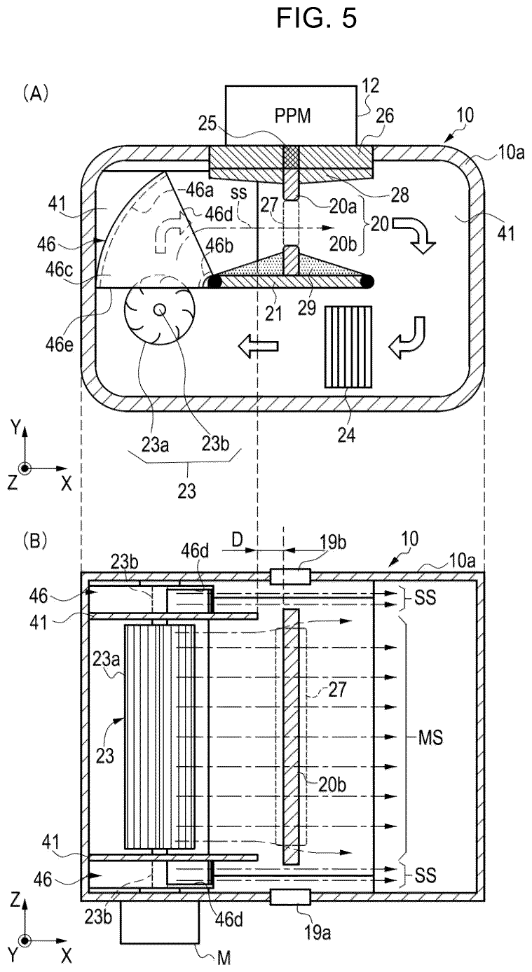

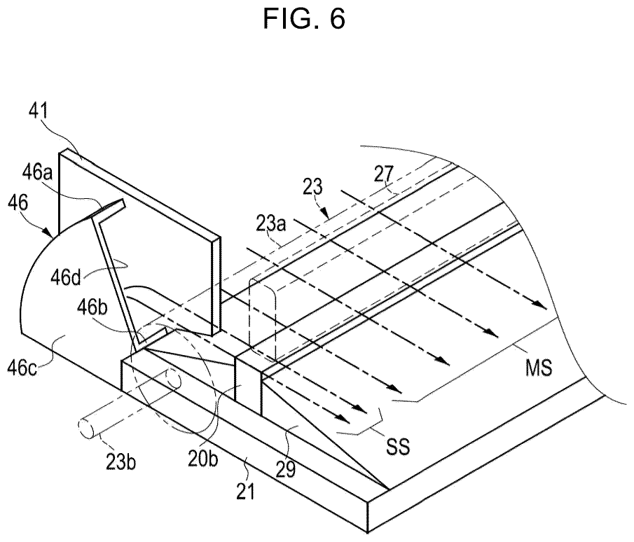

FIGS. 5 and 6 show the configuration of the laser chamber 10 according to the second embodiment. (A) of FIG. 5 is a side view of the container 10a, and (B) of FIG. 5 is a plan view of the container 10a. In the second embodiment, in addition to the pair of first guides 41, a pair of outer guides 46 is provided in the container 10a. FIG. 6 is a perspective view showing the configuration of the first guide 41 and the outer guide 46.

The pair of outer guides 46 are arranged opposite to each other in the axis direction so as to sandwich the pair of first guides 41, and rectify the laser gas flowing outside the pair of first guides 41.

In the second embodiment, the pair of outer guides 46 are each cylindrical as an example. That is, each of the pair of outer guides 46 includes an outer peripheral wall 46a, an inner peripheral wall 46b, and a side wall 46c. The outer peripheral wall 46a and the inner peripheral wall 46b are substantially arc-shaped about the rotary shaft 23b and have widths in the axis direction. The side wall 46c is a parallel plate substantially parallel to the first guide 41. The outer guide 46 defines, together with the first guide 41, an internal space having a sector-shaped sectional shape outside the first guide 41 by the outer peripheral wall 46a, the inner peripheral wall 46b, and the side wall 46c. In the internal space, the discharge space 27 side is opened through an opening 46d of the outer guide 46, and the fan 23 side is opened through an opening 46e. The opening 46e functions as an inlet port through which the laser gas flows into the internal space, and the opening 46d functions as an outlet port through which the laser gas flows out from the internal space toward the discharge space 27. Being cylindrical means a configuration having such an internal space with the two openings 46d, 46e. The outer guide 46 is formed of, for example, a metal material.

### 3.2 Operation

Operation of the gas laser device 2 according to the second embodiment is similar to that of the first embodiment except that the effect caused by provision of the pair of outer guides 46 in addition to the first guides 41 in the container 10a is different.

As shown in (B) of FIG. 5, the laser gas flows toward the discharge space 27 due to the rotation of the fan 23. In the second embodiment, the pair of first guides 41 are arranged respectively on both sides of the fan body 23a. The flow of the laser gas toward the outside of the discharge space 27 in the longitudinal direction is restricted by the pair of first guides 41. The flow of the laser gas inside the pair of first guides 41 is generated directly from the fan body 23a sandwiched by the pair of first guides 41. In the second embodiment, when this flow is regarded as a main flow MS, a branch flow SS is also generated by the outer guides 46 outside the pair of first guides 41. The laser gas also flows outside in the axis direction of the fan body 23a, and a part of the laser gas flows in from the opening 46e of the outer guide 46 and flows out from the opening 46d. This laser gas becomes the branch flow SS. The branch flow SS is generated along the flow direction of the main flow MS outside, in the longitudinal direction, of the discharge space 27.

### 3.3 Effect

In the second embodiment, the branch flow SS of the laser gas is generated, outside in the longitudinal direction, of the discharge space 27 by the pair of outer guides 46. The main flow MS of the laser gas tends to diffuse outward in the vicinity of the end in the longitudinal direction of the discharge space 27, but the diffusion of the main flow MS is suppressed by the branch flow SS functioning as an air screen. Accordingly, the decrease in the flow velocity of the laser gas in the vicinity of the end of the discharge space 27 in the longitudinal direction is suppressed, and the discharge products remaining in the discharge space 27 are reduced, so that the stability of discharge is improved.

In the container 10a, due to structural constraints such as the length of the fan body 23a, a surplus flow of the laser gas flowing in a direction different from the main flow MS is generated in the vicinity of the end in the axis direction of the fan 23. The branch flow SS utilizes the surplus flow of the laser gas. Therefore, the energy efficiency is better than that in the case in which a dedicated rectifying mechanism using drive energy other than the fan 23 is used.

The pair of outer guides 46 are each cylindrical. Accordingly, the flow velocity of the branch flow SS generated by the outer guides 46 is increased, so that the effect of suppressing diffusion of the main flow MS is improved.

Further, since the pair of outer guides 46 are formed of a metal material, workability is excellent. Since the pair of outer guides 46 are arranged at positions relatively far from the discharge space 27, even a metal material does not affect discharge. Here, the outer guides 46 may be formed of an insulating material. Further, the outer guides 46 may not be cylindrical. Further, the side wall 46c of the outer guide 46 may also serve as the inner wall of the container 10a. However, since it becomes easier to design the inner wall of the side wall 46c so that rectifying action of the laser gas is further improved, it is preferable to form the side wall 46c separately from the inner wall of the container 10a.

### 4. Third Embodiment

### 4.1 Configuration

The gas laser device 2 according to a third embodiment of the present disclosure has a configuration similar to that of the gas laser device 2 according to the first embodiment except that the configuration of the laser chamber 10 is different.

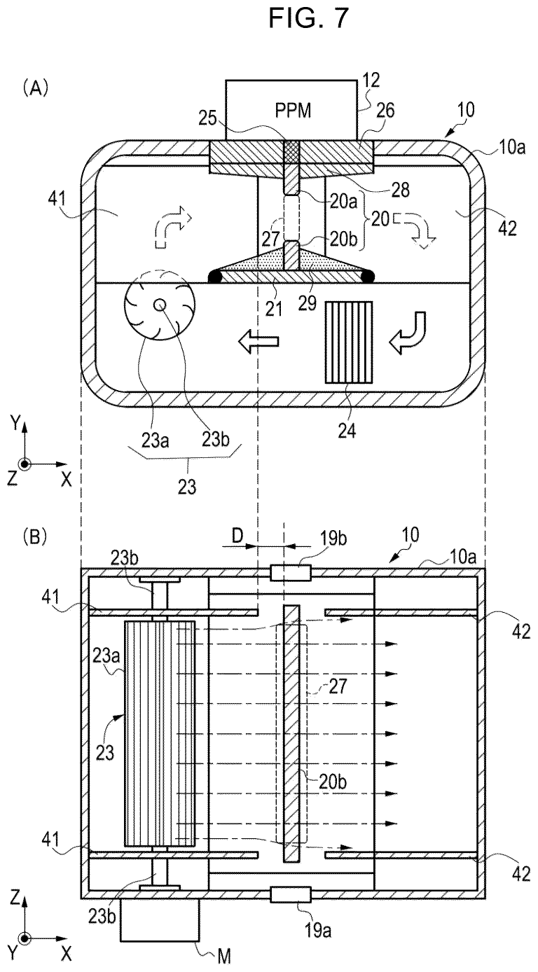

FIG. 7 shows the configuration of the laser chamber 10 according to the third embodiment. (A) of FIG. 7 is a side view of the container 10a, and (B) of FIG. 7 is a plan view of the container 10a. In the third embodiment, in addition to the pair of first guides 41, a pair of second guides 42 are arranged in the container 10a. As described above, the pair of first guides 41 are arranged on the upstream side, which is on the fan 23 side, in the flow direction (X direction) of the laser gas passing through the discharge space 27, and the pair of second guides 42 are arranged on the downstream side, which is on the opposite side with respect to the discharge space 27. The pair of second guides 42 rectify the laser gas flowing out from the discharge space 27, while the pair of first guides 41 rectify the laser gas toward the discharge space 27.

The configuration of the pair of second guides 42 is similar to that of the pair of first guides 41. Naturally, since the fan 23 is not arranged downstream of the pair of second guides 42, the pair of second guides 42 does not sandwich the fan body 23a, but the distance between the pair of second guides 42 in the longitudinal direction of the discharge space 27 is similar to that of the pair of first guides 41.

Further, in the flow direction (X direction) of the laser gas passing through the discharge space 27, the pair of first guides 41 and the pair of second guides 42 are arranged at an interval corresponding to the width of the discharge space 27 in the X direction. This is because the discharge space 27 serves as the optical path of the UV light. In the third embodiment as well, as in the first embodiment, the pair of first guides 41 are arranged as being spaced apart from the discharge electrode 20 by the distance D. The pair of second guides 42 are also arranged as being spaced apart from the discharge electrode 20 by the distance D. From the viewpoint of suppressing diffusion of the laser gas, it is preferable to shorten the distance D.

### 4.2 Operation

Operation of the gas laser device 2 according to the second embodiment is similar to that of the first embodiment except that the effect caused by provision of the pair of second guides 42 in addition to the pair of first guides 41 in the container 10a is different.

As shown in (B) of FIG. 7, the laser gas flows toward the discharge space 27 due to the rotation of the fan 23. In the third embodiment, the flow of the laser gas toward the outside of the discharge space 27 in the longitudinal direction is restricted by the pair of first guides 41. On the other hand, in the third embodiment, since the pair of second guides 42 is provided, the flow of the laser gas downstream of the discharge space 27 is rectified.

### 4.3 Effect

In the third embodiment, the flow velocity of the laser gas on the downstream side is increased by the rectifying action of the pair of second guides 42, and the flow velocity of the laser gas passing through the discharge space 27 on the upstream side is increased as well. Accordingly, diffusion and the decrease in the flow velocity of the laser gas in the vicinity of the end of the discharge space 27 in the longitudinal direction are suppressed. As a result, the discharge products remaining in the discharge space 27 are reduced, so that the stability of discharge is improved.

### 5. Fourth Embodiment

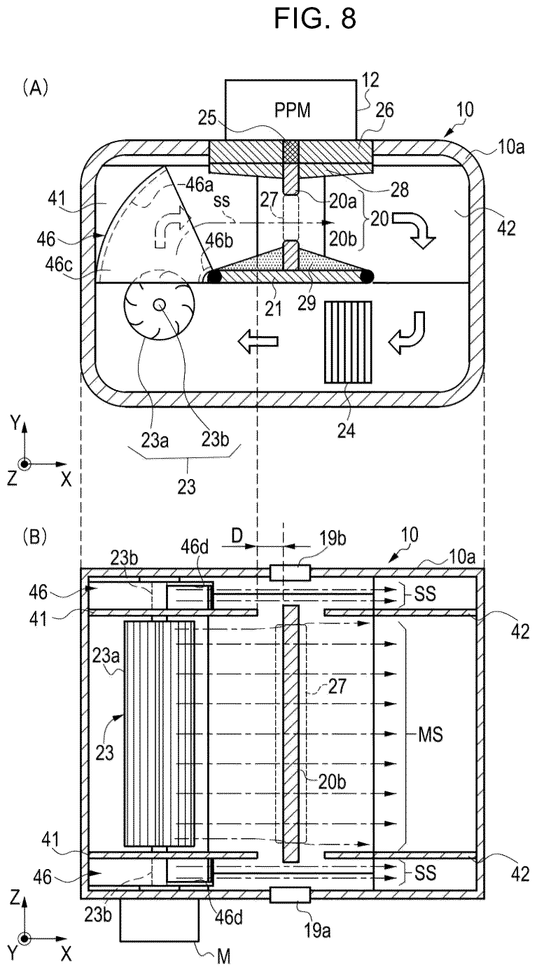

The fourth embodiment shown in FIG. 8 has a configuration in which the pair of outer guides 46 of the second embodiment shown in FIGS. 5 and 6 and the pair of second guides 42 of the third embodiment shown in FIG. 7 are combined. Operation of the fourth embodiment is substantially similar to that of the second and third embodiments. The fourth embodiment provides a synergistic effect by combining the configurations of the second embodiment and the third embodiment.

### 6. Fifth Embodiment

### 6.1 Configuration

The gas laser device 2 according to a fifth embodiment of the present disclosure has a configuration similar to that of the gas laser device 2 according to the fourth embodiment except that the configuration of the laser chamber 10 is different.

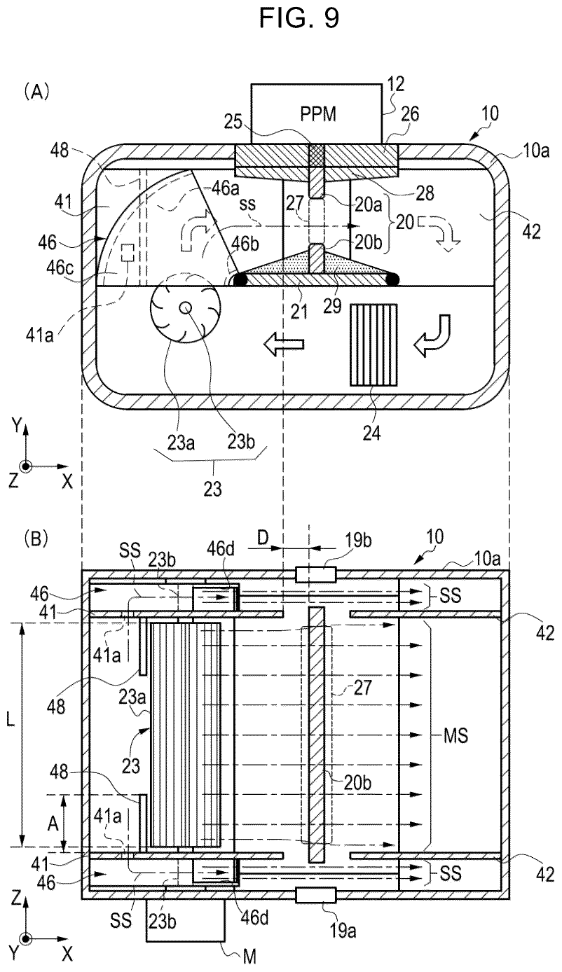

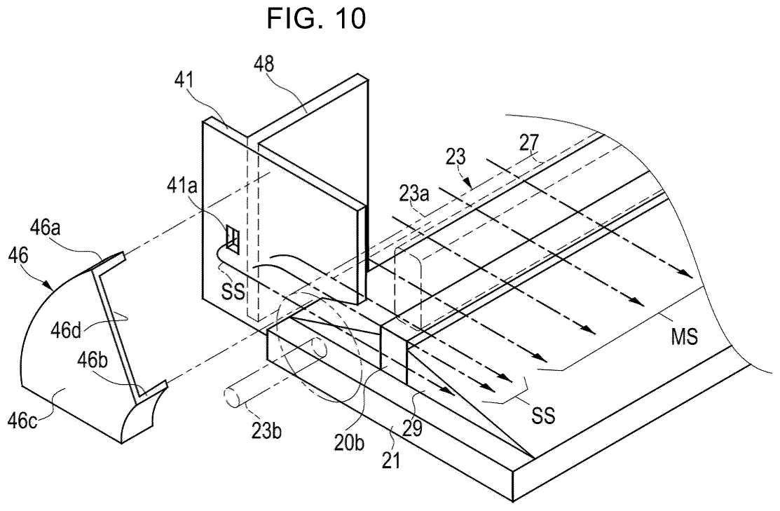

FIGS. 9 and 10 show the configuration of the laser chamber 10 according to the fifth embodiment. (A) of FIG. 9 is a side view of the container 10a, and (B) of FIG. 9 is a plan view of the container 10a. In the fifth embodiment, each of the pair of first guides 41 on the upstream side is provided with an introduction port 41a for introducing the laser gas from inside the first guides 41 into the corresponding outer guide 46 located outside thereof. FIG. 10 is a perspective view showing the configuration of the first guide 41 and the outer guide 46.

Further, a partition wall 48 extending toward the center in the axis direction of the rotary shaft 23b is arranged on the inner wall of each of the pair of first guides 41. The partition wall 48 is arranged between the introduction port 41a and the fan 23 in the X direction. The partition wall 48 and the inner wall of the container 10a define a bypass flow path through which the laser gas flows toward the introduction port 41a.

A length A of the partition wall 48 in the Z direction is set, for example, to 10% or more of the length L of the fan body 23a in the longitudinal direction.

### 6.2 Operation

Operation of the gas laser device 2 according to the fifth embodiment is substantially similar to that of the fourth embodiment except that the effect caused by provision of the pair of the introduction port 41a and the partition wall 48 in the container 10a is different.

As shown in (B) of FIG. 9, the laser gas flows toward the discharge space 27 due to the rotation of the fan 23. In the fifth embodiment, a part of the main flow MS generated by the fan 23 passes through the bypass flow path defined by the partition wall 48 and the inner wall of the container 10a and is introduced into the corresponding outer guide 46 from the introduction port 41a. Inside the outer guides 46, the laser gas flowing in from the opening 46e and the laser gas introduced from the introduction port 41a merge, and the merged laser gas flows out from the opening 46d as the branch flow SS. The laser gas introduced from the introduction port 41a is a part of the main flow MS, and therefore the flow velocity is high. Therefore, the flow velocity of the branch flow SS is increased. The branch flow SS functions as an air screen for restricting the flow of the laser gas toward the outside of the discharge space 27 in the longitudinal direction. On the other hand, in the fifth embodiment, since the pair of second guides 42 is provided, the flow of the laser gas downstream of the discharge space 27 is rectified.

### 6.3 Effect

In the fifth embodiment, since a part of the main flow MS is introduced from the introduction port 41a toward the outer guide 46, the flow velocity of the branch flow SS flowing out from the outer guide 46 is increased. This branch flow SS can further restrict the flow of the laser gas toward the outside of the discharge space 27 in the longitudinal direction. As a result, the discharge products remaining in the discharge space 27 are reduced, so that the stability of discharge is improved.

In the fifth embodiment, the pair of second guides 42 are provided as in the third embodiment, but the pair of second guides 42 may not be provided.

### 7. Electronic Device Manufacturing Method

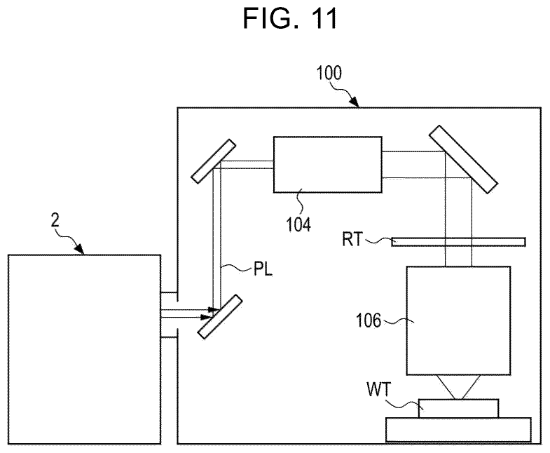

FIG. 11 schematically shows a configuration example of the exposure apparatus 100. The exposure apparatus 100 includes an illumination optical system 104 and a projection optical system 106. For example, the illumination optical system 104 illuminates a reticle pattern of a reticle (not shown) arranged on a reticle stage RT with the pulse laser light PL incident from the gas laser device 2. The projection optical system 106 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 100 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

Here, not limited to the manufacturing of an electronic device, the gas laser device 2 may be used for laser processing such as drilling.

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A laser chamber comprising:
a container configured to accommodate a laser gas;
a discharge electrode configured of a pair of electrodes arranged in the container;
a cross flow fan including a fan body configured to cause the laser gas to circulate in the container, and a rotary shaft protruding from both sides of the fan body; and
a pair of first guides arranged opposite to each other in an axis direction of the rotary shaft so as to sandwich at least a part of the fan body, and configured to rectify the laser gas toward a discharge space between the pair of electrodes.

2. The laser chamber according to claim 1,
wherein each of the pair of first guides is plate-shaped and extends in a direction orthogonal to the axis direction.

3. The laser chamber according to claim 1,
further comprising a pair of outer guides arranged opposite to each other in the axis direction so as to sandwich the pair of first guides, and configured to rectify the laser gas flowing outside the pair of first guides.

4. The laser chamber according to claim 3,
wherein each of the pair of outer guides is cylindrical.

5. The laser chamber according to claim 1,
wherein, in addition to the pair of first guides, a pair of second guides configured to rectify the laser gas flowing out from the discharge space are arranged.

6. The laser chamber according to claim 5,
wherein the pair of first guides and the pair of second guides are arranged at an interval corresponding to the discharge space in a flow direction of the laser gas passing through the discharge space.

7. The laser chamber according to claim 5,
further comprising a pair of outer guides arranged opposite to each other in the axis direction so as to sandwich the pair of first guides, and configured to rectify the laser gas flowing outside the pair of first guides.

8. The laser chamber according to claim 3,
wherein each of the pair of first guides is provided with an introduction port for introducing the laser gas from inside the pair of first guides into the corresponding outer guide located outside thereof.

9. The laser chamber according to claim 1,
further comprising a support member supporting an electrode closer to the cross flow fan out of the pair of electrodes,
wherein the pair of first guides extend at least to a bottom surface of the support member in a discharge direction of the pair of electrodes.

10. The laser chamber according to claim 1,
wherein each of the pair of first guides is formed of an insulating material.

11. A gas laser device including an optical resonator and a laser chamber arranged such that an optical path of the optical resonator passes therethrough and configured to output laser light,
the laser chamber including:
a container configured to accommodate a laser gas;
a discharge electrode configured of a pair of electrodes arranged in the container;
a cross flow fan including a fan body configured to cause the laser gas to circulate in the container, and a rotary shaft protruding from both sides of the fan body; and
a pair of first guides arranged opposite to each other in an axis direction of the rotary shaft so as to sandwich at least a part of the fan body, and configured to rectify the laser gas toward a discharge space between the pair of electrode.

12. An electronic device manufacturing method, comprising:
generating laser light using a gas laser device;
outputting the laser light to an exposure apparatus; and
exposing a photosensitive substrate to the laser light in the exposure apparatus to manufacture an electronic device,
the gas laser device including an optical resonator and a laser chamber arranged such that an optical path of the optical resonator passes therethrough and being configured to output the laser light, and
the laser chamber including:
a container configured to accommodate a laser gas;
a discharge electrode configured of a pair of electrodes arranged in the container;
a cross flow fan including a fan body configured to cause the laser gas to circulate in the container, and a rotary shaft protruding from both sides of the fan body; and
a pair of first guides arranged opposite to each other in an axis direction of the rotary shaft so as to sandwich at least a part of the fan body, and configured to rectify the laser gas toward a discharge space between the pair of electrode.
